(19) United States
(12) Patent Application Publication
(10) Pub. No.: US 2021/0050560 A1
(43) Pub. Date: Feb. 18, 2021

(54) FLEXIBLE DISPLAY PANEL AND FLEXIBLE DISPLAY DEVICE

(71) Applicant: Everdisplay Optronics (Shanghai) Co.,Ltd., Shanghai (CN)

(72) Inventor: Sheng GAO, Shanghai (CN)

(73) Assignee: Everdisplay Optronics (Shanghai) Co.,Ltd., Shanghai (CN)

(21) Appl. No.: 16/978,896

(22) PCT Filed: Jun. 25, 2019
(86) PCT No.: PCT/CN2019/092821

§ 371 Date: Sep. 8, 2020

(30) Foreign Application Priority Data
Apr. 26, 2018 (CN) 201810384973.8

(51) Int. Cl. H01L 51/56; H01L 27/32

(52) U.S. Cl. CPC H01L 51/56; H01L 27/3272; H01L 27/3276

(57) ABSTRACT

A flexible display panel includes a flexible substrate, a buffer layer, a first insulating layer including at least two sub insulating layers, and an organic light-emitting structure which are laminated, the display panel further includes a conductive layer, and the conductive layer is located between the flexible substrate and the organic light-emitting structure.

### CROSS-REFERENCE TO RELATED APPLICATIONS

The present application is based upon International Application No. PCT/CN2019/092821, filed on Jun. 25, 2019, which is based upon and claims priority to Chinese patent application No. 201810384973.8, filed on Apr. 26, 2018, the contents of both of which are hereby incorporated by reference in its entirety.

### TECHNICAL FIELD

Embodiments of the present disclosure relate to the field of display technology, and in particular, to a flexible display panel and a flexible display device.

### BACKGROUND

With the advancement of technology, flexible display technology has become an important branch in the field of display technology. A flexible display panel has the advantages of light weight, portability, and excellent pictures, and has been more and more widely used.

### SUMMARY

The present disclosure provides a flexible display panel and a flexible display device.

In a first aspect of embodiments of the present disclosure, there is provided a flexible display panel which includes a flexible substrate, a buffer layer, a first insulating layer including at least two sub insulating layers, and an organic light-emitting structure that are laminated:

the display panel further includes a conductive layer;

the conductive layer is located between the flexible substrate and the organic light-emitting structure.

Further, the conductive layer is located between the flexible substrate and the buffer layer, or between the buffer layer and the first insulating layers, or between the at least two sub insulating layers of the first insulating layer.

Further, a surface resistivity of the conductive layer is less than or equal to 10¹¹Ω.

Further, a material of the conductive layer is amorphous silicon, molybdenum, aluminum-titanium alloy, copper or nano-silver.

Further, a thickness of the conductive layer is from 1 nm to 1 μm.

Further, a distance between the conductive layer and the flexible substrate in a direction perpendicular to the flexible substrate is less than or equal to 100 μm.

Further, the first insulating layers include a first sub insulating layer and a second sub insulating layer, and the first sub insulating layer is located on a side of the second sub insulating layer adjacent to the flexible substrate.

Further, the organic light-emitting structure includes a driving function layer and a light-emitting function layer, and the driving function layer is configured to drive the light-emitting function layer to emit light;

the driving function layer includes a gate metal layer, an active layer, and a source-drain metal layer:

the active layer is located on a side of the source-drain metal layer away from the light-emitting function layer, and the gate metal layer is located between the active layer and the source-drain metal layer; or the gate metal layer is located on a side of the active layer adjacent to the flexible substrate.

Further, a material of the flexible substrate is Polyimide (PI) or Poly Ethylene Terephthalate (PET).

Further, a material of the buffer layer and the first insulating layers is silicon nitride or silicon oxide.

In a second aspect of the embodiments of the present disclosure, there is further provided a flexible display device including the flexible display panel according to the first aspect.

### BRIEF DESCRIPTION OF THE DRAWINGS

In order to clearly describe the technical solutions in the embodiments of the present application, the accompanying drawings which are referred to in the description of the embodiments will be briefly described below. Obviously, the drawings in the following description show merely some embodiments of the present application, and a person of ordinary skill in the art may still derive other drawings from these accompanying drawings without creative efforts.

FIG. 1 is a schematic structural diagram of a flexible display panel provided in an embodiment of the present disclosure;

FIG. 2 is a schematic structural diagram of another flexible display panel provided in an embodiment of the present disclosure;

FIG. 3 is a schematic structural diagram of yet another flexible display panel provided in an embodiment of the present disclosure;

FIG. 4 is a schematic structural diagram of yet another flexible display panel provided in an embodiment of the present disclosure;

FIG. 5 is a schematic structural diagram of yet another flexible display panel provided in an embodiment of the present disclosure;

FIG. 6 is a schematic structural diagram of a flexible display device provided in an embodiment of the present disclosure.

### DETAILED DESCRIPTION

The present disclosure will be further described in detail below with reference to the drawings and embodiments. It can be understood that the specific embodiments described herein are only used to explain the present disclosure, rather than to limit the present disclosure. In addition, it should be noted that, for ease of description, the drawings only show part of the structure related to the present disclosure but not all of the structure.

In the prior art, a flexible substrate of the flexible display panel is prone to be polarized, and the polarized charges will cause image sticking of the flexible display panel and affect the display effect of the flexible display panel. Taking an Organic Light-Emitting Diode (OLED) as an example, when the flexible display panel operates, it may stay on a certain picture for a long time. In this case, the flexible substrate of the flexible display panel is prone to be polarized and produces polarized charges. Thereafter, when the picture of the flexible display panel is switched, the polarized charges on the flexible substrate may cause an image sticking phenomenon on the flexible display panel, which affects the display effect and user experience of the flexible display panel.

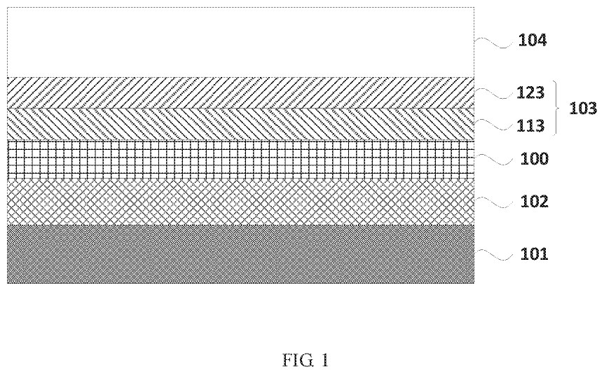

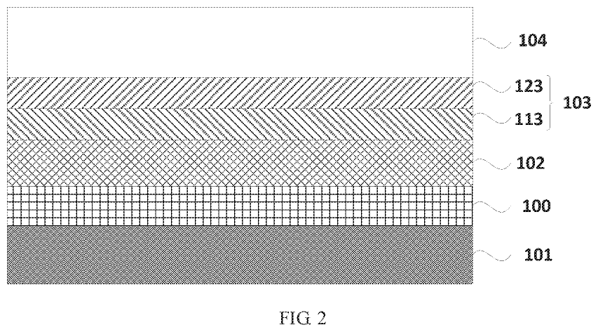

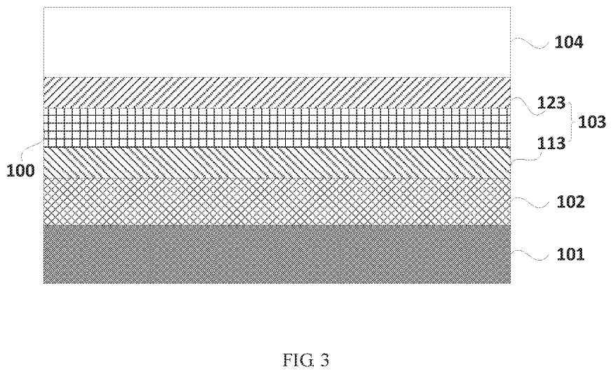

FIG. 1 is a schematic structural diagram of a flexible display panel provided in an embodiment of the present disclosure, FIG. 2 is a structural schematic diagram of another flexible display panel provided in an embodiment of the present disclosure, and FIG. 3 is a structure schematic diagram of yet another flexible display panel provided in an embodiment of the present disclosure. Optionally, referring to FIGS. 1-3, the flexible display panel can include a flexible substrate 101, a buffer layer 102, a first insulating layer 103 including at least two sub insulating layers, and an organic light emitting structure 104 which are laminated; the display panel can further include a conductive layer 100; and the conductive layer 100 can be located between the flexible substrate 101 and the buffer layer 102, between the buffer layer 102 and the first insulating layer 103, or between the at least two sub insulating layers of the first insulating layer 103.

Specifically, in the prior art, the organic light-emitting structure 104 of the flexible display substrate includes a circuit for controlling the operation of the flexible display panel, and when the flexible display panel is operated, movement of charges in the circuit of the organic light-emitting structure 104 can form a current, and at the same time, the charges can also generate an electric field, which can act on the flexible substrate 101 to polarize the flexible substrate 101 and generate polarized charges. A side of the flexible substrate 101 that is close to the organic light emitting structure 104 and a side of the flexible substrate 101 that is far away from the organic light emitting structure 104 are respectively polarized to produce charges of different electrical properties. When the flexible display panel displays a certain picture for a long time, the charges in the organic light-emitting structure 104 will have a relatively strong polarization effect on the flexible substrate 101, resulting in more polarized charges being generated on the flexible substrate 101. After the picture of the flexible display panel is switched, the electric field generated by the polarized charges on the flexible substrate 101 will affect the charge distribution in the circuit of the organic light-emitting structure 104, which in turn will cause the image sticking phenomenon of the flexible display panel.

By providing the conductive layer 100 of a strong conductive capability between the flexible substrate 101 and the organic light-emitting structure 104 of the flexible display panel, the polarized charges on the flexible substrate 101 can be shielded and the image sticking phenomenon during the displaying process of the flexible display panel can be eliminated. Specifically, the main functions of the conductive layer 100 include two aspects. In one aspect, when the flexible display panel stays on a certain picture for a long time, the conductive layer 100 can shield the polarization effect of the organic light-emitting structure 104 on the flexible substrate 101, reduce the number of charges polarized on the flexible substrate 101 and reduce a degree of charge polarization on the flexible substrate 101. When the number of charges polarized on the flexible substrate 101 decreases, the polarization electric field generated by the flexible substrate 101 is weakened and has a weak effect on the organic light emitting structure 104, and thus the image sticking of the flexible display panel can be reduced. In the other aspect, the conductive layer 100 can also shield the effect of the polarized charges of the flexible substrate 101 on the charge distribution in the organic light emitting structure 104. Therefore, the conductive layer 100 can not only reduce the polarization effect of the current in the organic light-emitting structure 104 on the flexible substrate 101, but also eliminate the effect of the polarized charges of the flexible substrate 101 on the charge distribution in the organic light-emitting structure 104, and thus the conductive layer 100 can eliminate the image sticking phenomenon of the flexible display panel.

It should be noted that the image sticking is generated due to the polarization of the charges on the flexible substrate 101, and the charge polarization originates from the polarization effect of the electric field in the organic light emitting structure 104 on the flexible substrate 101. Therefore, in order to avoid the image sticking phenomenon, the conductive layer 100 needs to be disposed between the flexible substrate 101 and the organic light emitting structure 104. The conductive layer 100 can be located between the flexible substrate 101 and the buffer layer 102, between the buffer layer 102 and the first insulating layer 103, or between the at least two sub insulating layers of the first insulating layer 103. On the premise that the conductive layer 100 is located between the flexible substrate 101 and the organic light emitting structure 104, the position of the conductive layer 100 is not specifically limited in the present disclosure. However, it should be noted that, in order to ensure a normal operation of the flexible display panel, the conductive layer 100 needs to avoid contacting with a conductive structure in the organic light-emitting structure 104, so as not to affect the normal operation of the flexible display panel.

In the flexible display panel provided in the embodiments of the present disclosure, the conductive layer of good conductivity is provided between the flexible substrate and the organic light-emitting structure, which can both reduce the polarization effect of the organic light-emitting structure on the flexible substrate and shield the effect of the polarized charges of the flexible substrate on the organic light-emitting structure, so as to avoid the charge distribution on the organic light-emitting structure from being affected by the polarized charges on the flexible substrate, thereby achieving the effect of eliminating the image sticking phenomenon of the flexible display panel and avoiding occurrence of the image sticking phenomenon on the flexible display panel.

Optionally, a surface resistivity of the conductive layer 100 is less than or equal to 10¹¹ Ω·cm. It can be understood that a conductor has an electrostatic shielding effect on the electric field, and the smaller the surface resistivity of the conductive layer 100 is, the better the electrostatic shielding effect is. Therefore, the smaller the surface resistivity of the conductive layer 100 is, the stronger its capability to shield the charge action between the organic light emitting structure 104 and the flexible substrate 101 is.

Optionally, the material of the conductive layer 100 can be amorphous silicon, molybdenum, aluminum-titanium alloy, copper, or nano-silver. Specifically, the microstructure of amorphous silicon is mostly distributed in a grid shape, and there are a large number of defects inside, which makes amorphous silicon have a certain conductivity. For semiconductor materials, the higher the temperature, the stronger the conductivity. Therefore, the conductivity of amorphous silicon will be significantly increased with the increase of temperature. Due to a certain amount of heat generated by the flexible display panel in operation, the surface resistivity of the conductive layer 100 made of the amorphous silicon is small. Molybdenum is an excessive elemental metal with a resistivity of 5.2×10⁻⁸ Ω·m at 0° C., which is a good conductive material. The resistivity of aluminum-titanium alloy and copper is respectively 5.2×10⁻⁸ Ω·m and 1.7×10⁻⁸ Ω·m at normal temperature, which are of good conductivity. Ordinary metallic silver has a resistivity of 1.6×10⁻⁸ Ω·m at normal temperature, and a silver nanomaterial which is a nano-scale material made of metallic silver is generally superior to ordinary metallic silver in the physical properties. Therefore, it can be understood that the resistivity of the nano-silver particles is less than 1.6×10⁻⁸ Ω·m. Since the conductivity of molybdenum, aluminum-titanium alloy, copper and nano-silver are all stronger than that of the amorphous silicon material, the surface resistivity of the conductive layer 100 made of molybdenum, aluminum-titanium alloy, copper or nano-silver is smaller and can better eliminate the image sticking on the flexible display panel.

Optionally, a thickness of the conductive layer 100 may be 1 nm-1 μm. It can be understood that, since the conductive layer 100 has a good conductivity, the conductive layer 100 with a thickness of 1 nm or more can provide a good shielding function and eliminate the image sticking on the flexible display panel. If the thickness of the conductive layer 100 is too small, its electrostatic shielding capability will be affected, and the image sticking on the flexible display panel cannot be eliminated well. However, if the thickness of the conductive layer 100 is too large, for example, more than 1 μm, since the conductive layer 100 is disposed on the insulating material between the flexible substrate 101 and the organic light-emitting structure 104, a difficulty in a manufacturing process of the conductive layer 100 with an excessively large thickness increases, which leads to an increase in an overall manufacturing cost of the flexible display panel and which may affect the bending performance of the display panel. It should be noted that the above thickness range of 1 nm-1 μm is not a limitation on the thickness of the conductive layer 100, and those skilled in the art can set the thickness of the conductive layer 100 reasonably according to actual requirements, which is not limited in the embodiments of the present disclosure.

The conductive layer 100 can be prepared by a method such as Physical Vapor Deposition (PVD), Chemical Vapor Deposition (CVD) or Coating. PVD is a commonly used film preparation method and the prepared film has the advantages of high hardness, low friction coefficient, good wear resistance and chemical stability, and can be widely used in the preparation of display panels. When the CVD method is used to prepare a thin film, vapor containing gaseous or liquid reactant constituting the thin film element and other gases required for the reaction are often introduced into a reaction chamber, and a chemical reaction occurs on the substrate surface so as to form a thin film. The thin film prepared by the CVD method has the advantages of low deposition temperature, ease control of composition of the thin film, film thickness proportional to the deposition time, and good uniformity, repeatability and step coverage. When the conductive layer 100 is prepared by the coating method, it has the advantages of simple production process and uniform thickness of the conductive layer 100. In addition, those skilled in the art can also choose other possible methods to form the conductive layer 100 as needed.

Optionally, a distance between the conductive layer 100 and the flexible substrate 101 in a direction perpendicular to the flexible substrate 101 is less than or equal to 100 μm. When the conductor material is closer to the charge source, the electrostatic shielding capability of the conductor is stronger. In order to improve the electrostatic shielding capability of the conductive layer 100 against the polarized charges on the flexible substrate 101, the smaller the distance between the conductive layer 100 and the flexible substrate 101 is, the stronger the electrostatic shielding capability of the conductive layer 100 is. It can be understood that the influence of the polarized charges of the flexible substrate 101 on the organic light-emitting structure 104 is a direct cause of image sticking. Therefore, in order to better eliminate the image sticking, the distance between the conductive layer 100 and the flexible substrate 101 is required to be less than or equal to 100 μm.

From further analysis of FIGS. 1-3, it can be seen that the conductive layer 100 in FIG. 2 is disposed on the side of the flexible substrate 101 close to the organic light-emitting structure 104, and the conductive layer 100 is disposed adjacent to the flexible substrate 101. Therefore, the distance between the conductive layer 100 and the flexible substrate 101 is the smallest. The conductive layer 100 in FIG. 3 is disposed between the at least two sub insulating layers of the first insulating layer 103, and the distance between the conductive layer 100 and the flexible substrate 101 is the largest. The conductive layer 100 in FIG. 1 is disposed between the buffer layer 102 and the first insulating layer 103, and the distance between the conductive layer 100 and the flexible substrate 101 is in between those of the structures shown in FIGS. 2 and 3. Therefore, preferably, the conductive layer 100 is disposed between the buffer layer 102 and the first insulating layer 103, and more preferably, the conductive layer 100 is located between the flexible substrate 101 and the buffer layer 102.

Optionally, continuing to refer to FIGS. 1-3, the first insulating layer 103 includes a first sub insulating layer 113 and a second sub insulating layer 123. The first sub insulating layer 113 can be located on the side of the second sub insulating layer 123 adjacent to the flexible substrate 101. It should be noted that the first sub insulating layer 113 can be of a silicon nitride (SiNx) material, and the second sub insulating layer 123 can be of a silicon oxide (SiOx) material. In the flexible display panel, silicon nitride can be used to block external water and oxygen from corroding the flexible display panel and protect the flexible display panel, silicon oxide has a thermal insulation function to prevent a large change in the temperature inside the flexible display panel which will cause damage of the flexible display panel. It can be understood that the first sub insulating layer 113 can also be located on the side of the second sub insulating layer 123 away from the flexible substrate 101. In this embodiment, the positional relationship between the first sub insulating layer 113 and the second sub insulating layer 123 is not specifically limited.

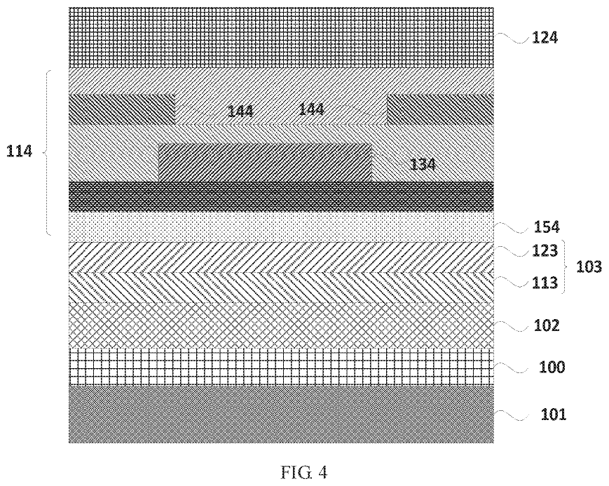

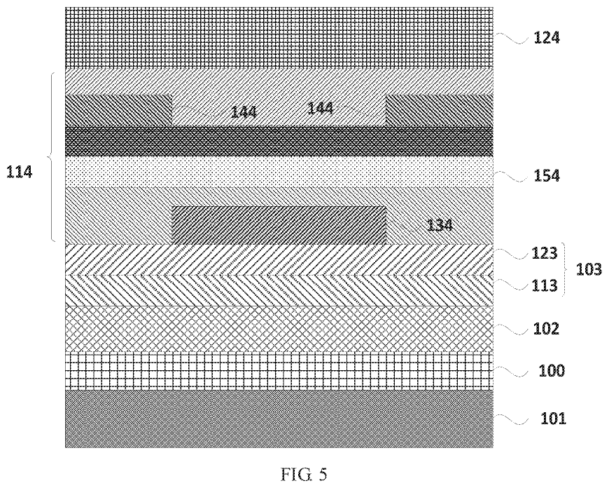

FIG. 4 is a schematic structural diagram of another flexible display panel provided in an embodiment of the present disclosure, and FIG. 5 is a structural schematic diagram of yet another flexible display panel provided in an embodiment of the present disclosure. Optionally, referring to FIGS. 4 and 5, the organic light-emitting structure includes a driving function layer 114 and a light-emitting function layer 124, and the driving function layer 114 is configured to drive the light-emitting function layer 124 to emit light; the driving function layer 114 can include a gate metal layer 134, an active layer 154 and a source-drain metal layer 144; the active layer 154 is located on a side of the source-drain metal layer 144 away from the light-emitting functional layer 124; the gate metal layer 134 is located between the active layer 154 and the source-drain metal layer 144 (referring to FIG. 4), or the gate metal layer 134 is located on a side of the active layer 154 adjacent to the flexible substrate 101 (referring to FIG. 5).

Specifically, the driving function layer 114 can have a Thin Film Transistor (TFT) structure. Common TFTs include a top gate type structure (referring to FIG. 4) and a bottom gate type structure (referring to FIG. 5). Further, the light-emitting function layer 124 specifically includes a cathode, an anode, and a pixel-defining layer. The light-emitting function layer 124 can be of a top emission type or a bottom emission type. On a side of the light-emitting functional layer 124 away from the driving functional layer 114, a packaging structure can also be included. It should be noted that, since the primary inventive point of this embodiment does not lie in the organic light-emitting structure 104, the driving function layer 114, the light-emitting function layer 124, and the packaging structure are not defined specifically in this embodiment.

Optionally, the material of the flexible substrate 101 is PI or PET. In order to meet the technical requirement that the flexible display panel is bendable, the flexible substrate 101 is generally made of organic materials. PI, as a special organic material, has a small thermal expansion coefficient, excellent mechanical properties and bendability. PET is also an organic material which has excellent physical and mechanical properties, good fatigue resistance and friction resistance in a wide temperature range. It should be noted that the flexible substrate 101 can also be made of other materials than PI or PET.

Optionally, the materials of the buffer layer 102 and the first insulating layer 113 are silicon nitride or silicon oxide. In the operation of the flexible display panel, the buffer layer 102 can be used to block external water and oxygen from corroding the flexible display panel and protect the flexible display panel. It should be noted that the buffer layer 102 and the first insulating layers 113 can be formed by using different manufacturing processes.

In the flexible display panel provided in the embodiments of the present disclosure, the conductive layer of good conductivity is provided between the flexible substrate and the organic light-emitting structure, which can both reduce the polarization effect of the organic light-emitting structure on the flexible substrate and shield the effect of the polarized charges of the flexible substrate on the organic light-emitting structure, so as to avoid the charge distribution on the organic light-emitting structure from being affected by the polarized charges on the flexible substrate, thereby achieving the effect of eliminating the image sticking phenomenon of the flexible display panel and avoiding occurrence of image sticking phenomenon on the flexible display panel.

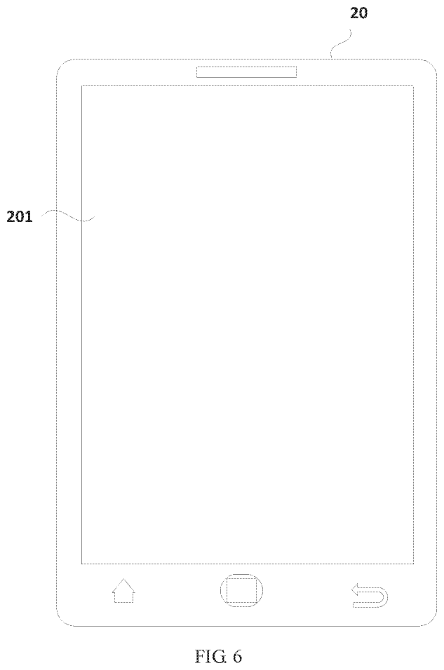

The embodiments of the present disclosure also provide a flexible display device. FIG. 6 is a schematic structural diagram of a flexible display device provided in an embodiment of the present disclosure. The flexible display device 20 can include the flexible display panel 201 provided in any embodiment of the present disclosure.

In the display device provided in the embodiments of the present disclosure, the conductive layer of good conductivity is provided between the flexible substrate and the organic light-emitting structure, which can both reduce the polarization effect of the organic light-emitting structure on the flexible substrate and shield the effect of the polarized charges of the flexible substrate on the organic light-emitting structure, so as to avoid the charge distribution on the organic light-emitting structure from being affected by the polarized charges on the flexible substrate, thereby achieving the effect of eliminating the image sticking phenomenon of the flexible display panel and avoiding occurrence of image sticking phenomenon on the flexible display panel.

It is to be noted that the above described are only the preferred embodiments of the present disclosure and the technical principles thereof. Those skilled in the art will understand that the present disclosure is not limited to the specific embodiments described herein, and various obvious changes, readjustments and substitutions can be made without departing from the protection scope of the present disclosure. Therefore, although the present disclosure has been described in detail through the above embodiments, the present disclosure is not limited to the above embodiments, and can also include other equivalent embodiments without departing from the concept of the present disclosure. The scope of the present disclosure is determined by the scope of the appended claims.

What is claimed is:

1. A flexible display panel, comprising:
a flexible substrate, a buffer layer, a first insulating layer including at least two sub insulating layers, and an organic light emitting structure that are laminated,
wherein the display panel further comprises a conductive layer, and
the conductive layer is located between the flexible substrate and the organic light emitting structure.

2. The flexible display panel according to claim 20, wherein a surface resistivity of the conductive layer is less than or equal to 10¹¹Ω.

3. The flexible display panel according to claim 2, wherein a material of the conductive layer is amorphous silicon, molybdenum, aluminum-titanium alloy, copper, or nano-silver.

4. The flexible display panel according to claim 20, wherein a thickness of the conductive layer is from 1 nm to 1 μm.

5. The flexible display panel according to claim 20, wherein a distance between the conductive layer and the flexible substrate in a direction perpendicular to the flexible substrate is less than or equal to 100 μm.

6. The flexible display panel according to claim 20, wherein the first insulating layer comprises a first sub insulating layer and a second sub insulating layer, and the first sub insulating layer is located on a side of the second sub insulating layer adjacent to the flexible substrate.

7. The flexible display panel according to claim 20, wherein,
the organic light-emitting structure comprises a driving function layer and a light-emitting function layer, and the driving function layer is configured to drive the light-emitting function layer to emit light;
the driving function layer comprises a gate metal layer, an active layer, and a source-drain metal layer; and
the active layer is located on a side of the source-drain metal layer away from the light-emitting function layer, and the gate metal layer is located between the active layer and the source-drain metal layer; or the gate metal layer is located on a side of the active layer adjacent to the flexible substrate.

8. The flexible display panel according to claim 1, wherein a material of the flexible substrate is polyimide (PI) or polyethylene terephthalate (PET).

9. The flexible display panel according to claim 1, wherein a material of the buffer layer and the first insulating layer are silicon nitride or silicon oxide.

10. A flexible display device, comprising a flexible display panel, the flexible display panel comprising a flexible substrate, a buffer layer, a first insulating layer including at least two sub insulating layers, and an organic light emitting structure that are laminated,
wherein the display panel further comprises a conductive layer, and
the conductive layer is located between the flexible substrate and the organic light emitting structure.

11. The flexible display device according to claim 10, wherein the conductive layer is located between the flexible substrate and the buffer layer, between the buffer layer and the first insulating layer, or between the at least two sub insulating layers of the first insulating layer.

12. The flexible display device according to claim 11, wherein a surface resistivity of the conductive layer is less than or equal to 10¹¹Ω.

13. The flexible display according to claim 12, wherein a material of the conductive layer is amorphous silicon, molybdenum, aluminum-titanium alloy, copper, or nano-silver.

14. The flexible display device according to claim 11, wherein a thickness of the conductive layer is from 1 nm to 1 μm.

15. The flexible display device according to claim 11, wherein a distance between the conductive layer and the flexible substrate in a direction perpendicular to the flexible substrate is less than or equal to 100 μm.

16. The flexible display device according to claim 11, wherein the first insulating layer comprises a first sub insulating layer and a second sub insulating layer, and the first sub insulating layer is located on a side of the second sub insulating layer adjacent to the flexible substrate.

17. The flexible display device according to claim 11, wherein,
the organic light-emitting structure comprises a driving function layer and a light-emitting function layer, and the driving function layer is configured to drive the light-emitting function layer to emit light;
the driving function layer comprises a gate metal layer, an active layer, and a source-drain metal layer; and
the active layer is located on a side of the source-drain metal layer away from the light-emitting function layer, and the gate metal layer is located between the active layer and the source-drain metal layer; or the gate metal layer is located on a side of the active layer adjacent to the flexible substrate.

18. The flexible display device according to claim 10, wherein a material of the flexible substrate is polyimide (PI) or polyethylene terephthalate (PET).

19. The flexible display device according to claim 10, wherein a material of the buffer layer and the first insulating layer are silicon nitride or silicon oxide.

20. The flexible display panel according to claim 1, wherein the conductive layer is located between the flexible substrate and the buffer layer, between the buffer layer and the first insulating layer, or between the at least two sub insulating layers of the first insulating layer.
